(19) United States
(12) Patent Application Publication
(10) Pub. No.: US 2026/0081094 A1
(43) Pub. Date: Mar. 19, 2026

(54) METHODS OF CALIBRATING A LANDING ANGLE OF AN ELECTRON BEAM

(71) Applicant: KLA CORPORATION, Milpitas, CA (US)

(72) Inventors: Da LI, Ann Arbor, MI (US); Miao WANG, Shanghai (CN); Yukun SUN, Canton, MI (US); Li WANG, Ann Arbor, MI (US)

(21) Appl. No.: 18/884,911

(22) Filed: Sep. 13, 2024

(51) Int. Cl. H01J 37/02

(52) U.S. Cl. CPC H01J 37/02; H01J 2237/2826

(57) ABSTRACT

A method of calibrating a landing angle of an electron beam includes fabricating a landing angle standard structure, determining a tilt angle of the landing angle standard structure relative a reference plane, scanning the landing angle standard structure to generate a plurality of images of the landing angle standard structure, determining a width difference between a first sidewall formed on the landing angle standard structure and a second sidewall formed on the landing structure, determining, using the width difference between the first sidewall and the second sidewall, a beam tilt of the electron beam, determining, by comparing the beam tilt of the electron beam to the tilt angle of the landing angle standard structure, the landing angle of the electron beam, and adjusting the electron beam, such that the landing angle of the electron beam is normal to a surface of the landing angle standard structure.

### FIELD OF THE INVENTION

The embodiments described herein relate to methods of electron beam calibration and, more specifically, to methods of calibrating a landing angle of an electron beam using a high aspect ratio standard structure.

### BACKGROUND

In the semiconductor manufacturing industry, trends have shifted from the use of planar structures to increasingly complex three-dimensional (“3D”) structures. This evolution has introduced new challenges in maintaining precise control over certain structure dimensions, including structure height, thickness, and sidewall angles. Moreover, the accuracy of electron beam measurements has become a factor in manufacturing semiconductor structures, particularly when inspecting high aspect ratio (“HAR”) structures.

For example, the accuracy of electron beam measurements may rely on precise alignment of the electron beam relative the structure being manufactured and/or inspected. In current semiconductor metrology tools, the alignment of the electron beam is used to ensure small beam spot size, which allows for the production of high-resolution imaging. However, traditional semiconductor metrology tools and alignment methods fail to compensate for tilt of the electron beam, which can lead to variations in measurements across different metrology tools and substantial measurement errors. Accordingly, a need exists for a method of calibrating an electron beam that ensures accurate and consistent measurements across various semiconductor metrology tools.

### SUMMARY OF THE DISCLOSURE

In the embodiments described herein, a method of calibrating a landing angle of an electron beam is disclosed. The method includes fabricating a landing angle standard structure; determining a tilt angle of the landing angle standard structure relative a reference plane; scanning the landing angle standard structure, using the electron beam, to generate a plurality of images of the landing angle standard structure; determining, using the plurality of images of the landing angle standard structure, a width difference between a first sidewall formed on the landing angle standard structure and a second sidewall formed on the landing structure; determining, using the width difference between the first sidewall and the second sidewall, a beam tilt of the electron beam; determining, by comparing the beam tilt of the electron beam to the tilt angle of the landing angle standard structure, the landing angle of the electron beam; and adjusting the electron beam, such that the landing angle of the electron beam is normal to a surface of the landing angle standard structure.

In further embodiments, a method of calibrating a landing angle of an electron beam is disclosed. The method includes fabricating, using an etching process, a landing angle standard structure having a pair of sidewalls, each of the pair of sidewalls being symmetrical; determining a tilt angle of the landing angle standard structure relative a reference plane, scanning the landing angle standard structure, using the electron beam, to generate a plurality of images of the landing angle standard structure; determining, using the plurality of images of the landing angle standard structure, a width difference between the pair of sidewalls of the landing angle standard structure; determining, by comparing the width difference between the pair of sidewalls and a height of the pair of sidewalls, a beam tilt of the electron beam; determining, by comparing the beam tilt of the electron beam to the tilt angle of the landing angle standard structure, the landing angle of the electron beam; and adjusting the electron beam, such that the landing angle of the electron beam is normal to a surface of the landing angle standard structure; wherein fabricating the landing angle standard structure further includes fabricating the landing angle standard structure as a high aspect ratio structure.

In other embodiments still, a method of fabricating a landing angle standard structure for calibrating a landing angle of an electron beam is disclosed. The method includes forming, using an etching process, the landing angle standard structure, such that the landing angle standard structure includes a pair of symmetrical sidewalls and a high aspect ratio, disposing an imaging layer over a surface of the landing angle standard structure, the imaging layer being formed of a first material that is different than a second material used to form the landing angle standard structure; and disposing the landing angle standard structure within an environment of the electron beam, such that the surface of the landing angle standard structure has a tilt angle relative the electron beam.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 is a side view of a structure undergoing a tilt calibration process, according to one or more embodiments shown and described herein;

FIG. 2A is a front side view of the structure of FIG. 1 undergoing a landing angle sweep with a first landing angle offset, according to one or more embodiments shown and described herein;

FIG. 2B is a front side view of the structure of FIG. 1 undergoing a landing angle sweep without a landing angle offset, according to one or more embodiments shown and described herein;

FIG. 2C is a front side view of the structure of FIG. 1 undergoing a landing angle sweep with a second landing angle offset, according to one or more embodiments shown and described herein;

FIG. 3A is a perspective view of the structure of FIG. 1 further including an imaging layer, according to one or more embodiments shown and described herein;

FIG. 3B is a perspective view of another embodiment of the structure of FIG. 1 further including an imaging layer, according to one or more embodiments shown and described herein;

FIG. 4A is a side view of a structure having a standardized landing angle, according to one or more embodiments shown and described herein; and

FIG. 4B is a side view of the structure of FIG. 1 having a determined landing angle, according to one or more embodiments shown and described herein.

### DETAILED DESCRIPTION

Embodiments disclosed herein relate to methods of calibrating a landing angle of an electron beam. In these embodiments, the method may involve fabricating a landing angle standard structure, determining a tilt angle of the landing angle standard structure relative a reference plane, scanning the landing angle standard structure, to generate a plurality of images of the landing angle standard structure, determining a width difference between a first sidewall formed on the landing angle standard structure and a second sidewall formed on the landing structure, determining a beam tilt of the electron beam, determining the landing angle of the electron beam, and adjusting the electron beam, such that the landing angle of the electron beam is normal to a surface of the landing angle standard structure. In the embodiments described herein, it should be appreciated that, by determining and accounting for the landing angle of the electron beam, the method described herein may allow for more accurate measurements of structure while minimizing deviations between metrology tools.

In the embodiments described herein, the term “landing angle” may refer to an angle at which an electron beam (or any other measurement beam) contacts a surface of a structure relative a defined reference plane. In some embodiments, the landing angle may be measured as the deviation of the beam relative a plane normal to the surface of the structure which the electron beam contacts during measurement. Determination and application of the landing angle will be described in additional detail herein.

In the embodiments described herein, the term “high aspect ratio” (“HAR”) may refer to a structure in which the aspect ratio of the structure exceeds 2.

As noted hereinabove, traditional metrology tools and electron beam alignment methods often fail to account for the landing angle of the electron beam, which may lead to numerous inefficiencies and inaccuracies. For example, it should be appreciated that the landing angle of the electron beam may vary between operating environments (e.g., metrology tools), which may result in inconsistent measurement results across different systems. Furthermore, these inconsistencies (e.g. deviations) can lead to significant measurement errors, particularly when inspecting HAR structures. In some embodiments, a landing angle error of less than 5 milliradians may result in a measurement error of greater than 5 percent when HAR reaching 20, which is unacceptable in modern semiconductor manufacturing and measurement.

The disclosed method of calibrating a landing angle of an electron beam aims to address these shortcomings by providing a more precise and reliable calibration method. In particular, the disclosed method utilizes a landing angle standard that includes symmetrical sidewalls, a high aspect ratio, and full conductivity. By referencing this standard as a baseline, the method may ensure consistent and accurate landing angle measurements across various metrology tools, thereby minimizing (or eliminating) variation between metrology tools.

Furthermore, the method described herein accounts for tilt (e.g., in the x-direction and y-direction, as will be described in additional detail herein) of the structure to reduce measurement errors. In these embodiments, accounting for the tilt of the structure may ensure that even small landing angle deviations are detected and corrected, which may allow for more accurate measurement and measurement of the structure.

Embodiments of methods for calibrating landing angles of electron beams will now be described in additional detail herein. The following will now describe these methods in more detail with reference to the drawings and where like numbers refer to like structures.

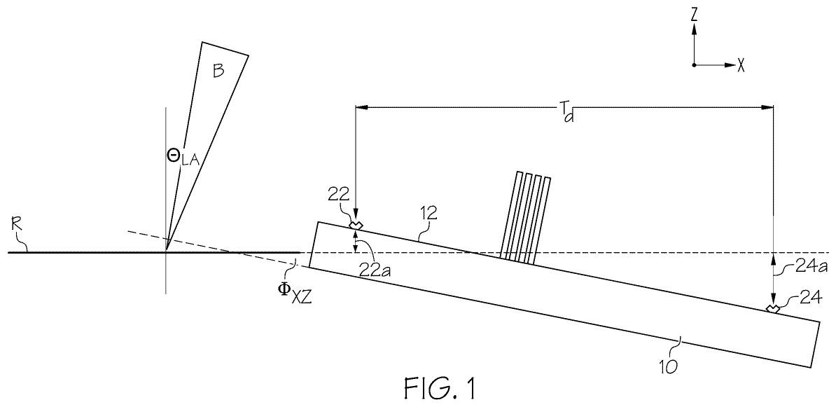

Referring now to FIGS. 1A-3B, a method of calibrating a landing angle Θ_{LA} of an electron beam B is depicted. As noted hereinabove, the landing angle Θ_{LA} may refer to the angle at which the electron beam B referenced to the wafer plane (e.g. reference plane, which is assume absolute horizontal). In these embodiments, the landing angle Θ_{LA} of the electron beam B may be determined by scanning (e.g., sweeping) the electron beam B over the structure 10, such that the electron beam B passes over a surface 12 of the structure 10 in a plurality of directions (e.g., in at least the x-direction and y-direction, as will be described in additional detail herein). In these embodiments, the structure 10 used to determine the landing angle Θ_{LA} may be a standardized structure, such that the structure may be fabricated to include a number of predetermined dimensions and measurements (e.g., height, width, sidewall angles, etc.). Accordingly, it should be understood that comparing the electron beam B to the structure 10 (e.g., standardized structure) may allow for a determination of the landing angle Θ_{LA} of the electron beam B. In the embodiments described herein, once the landing angle Θ_{LA} of the electron beam B is determined, the electron beam B may be adjusted to ensure that the electron beam B is normal to any structures (e.g., non-standardized structures) on the reference plane (e.g., wafer plane) being inspected by the electron beam B. Furthermore, it should be appreciated that, in other embodiments, the electron beam B may be used to inspect various structures without adjusting the landing angle Θ_{LA} of the electron beam B prior to measurement. In these embodiments, the landing angle Θ_{LA} determined utilizing the method described herein may be used to adjust any measurements and/or dimensions obtained using the electron beam B after the measurement of the relevant structures is complete, as will be described in additional detail herein.

In the embodiments depicted in FIGS. 1A-3B, the structure 10 may be a semiconductor structure, a semiconductor wafer, or any other similar 3D structure capable of being utilized as a standardized reference structure without departing from the scope of the present disclosure. Furthermore, although the method depicted in FIGS. 1A-3B is described as being used to calibrate an electron beam, it should be understood that the method may be similarly applied to any type of calibration beam (e.g., laser, etc.) without departing from the scope of the present disclosure.

Referring still to FIGS. 1-3B, and as should be appreciated in view of the foregoing, in some embodiments, the method of calibrating the landing angle Θ_{LA} of the electron beam B may initially involve fabricating the structure 10 that may be used as the standardized structure. For purposes of the present disclosure, the fabricated structure used to determine the landing angle Θ_{LA} of the electron beam B may be further referred to as a landing angle standard structure 10.

In these embodiments, the landing angle standard structure 10 may be fabricated to include a plurality of predetermined parameters, which may allow the structure to be used as a standardized reference for determining the landing angle Θ_{LA} of the electron beam B. For example, in the embodiments described herein, the landing angle standard structure 10 may be fabricated as an HAR structure. As provided herein, the aspect ratio of the landing angle standard structure 10 may be defined as the ratio of a height of the landing angle standard structure 10 relative a width of the landing angle standard structure 10. In these embodiments, it should be appreciated that fabricating the landing angle standard structure 10 as an HAR structure may improve the resolution of the disclosed calibration, such that small misalignments in the landing angle Θ_{LA} of the electron beam B may be identified. It should be further understood that, in the embodiments described herein, the calibration sensitivity (e.g., resolution) of the disclosed method may increase proportionally to the aspect ratio of the landing angle standard structure 10, such that increasing the aspect ratio of the landing angle standard structure 10 similarly increases the calibration sensitivity of the disclosed method.

Furthermore, although the aspect ratio of the landing angle standard structure 10 is defined as the ratio between the height and width of the landing angle standard structure 10, it should be appreciated that, in some embodiments, the landing angle standard structure 10 maybe an etched structure, such that the aspect ratio of the landing angle standard structure 10 may refer to a depth of the landing angle standard structure 10 relative the width of the landing angle standard structure 10. In these embodiments, increasing the depth of the landing angle standard structure 10 may act to increase the aspect ratio of the landing angle standard structure 10, and in turn, the calibration sensitivity of the disclosed method.

Referring still to FIGS. 1-3B, the landing angle standard structure 10 may also be fabricated to be a conductive structure. For example, in these embodiments, the electron beam B may be configured to obtain scanning electron microscope (“SEM”) images of the landing angle standard structure 10, which may be used to determine the landing angle Θ_{LA} of the electron beam B. In these embodiments, utilizing a conductive structure as the landing angle standard structure 10 may ensure that the SEM images captured by the electron beam B are not distorted, which may alleviate the risk of inaccurate measurements.

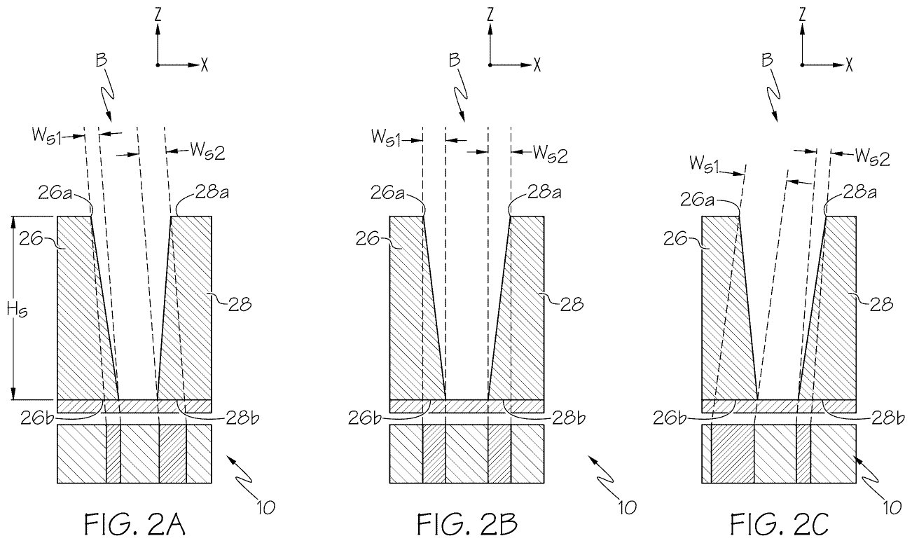

Furthermore, in the embodiments described herein, the landing angle standard structure 10 may be fabricated to have a pair of sidewalls 20, with the pair of sidewalls 20 being symmetrical (e.g., such that each of the pair of sidewalls 20 are a mirror image of one another). In these embodiments, the symmetry of the pair of sidewalls 20 may be utilized to aid in determining the landing angle Θ_{LA} of the electron beam B, as will be described in additional detail herein with reference to FIGS. 2A-2C.

In the embodiments described herein, it should be appreciated that a number of methods and/or etching techniques may be used to form the landing angle standard structure 10. For example, the landing angle standard structure 10 may be fabricated via reactive ion etching (“RIE”), deep reactive ion etching (“DRIE”), cryogenic deep silicon etching, inductively coupled plasma etching, wet etching, or any other similar process without departing from the scope of the present disclosure.

Referring now to FIG. 1, once the landing angle standard structure 10 has been fabricated, the method of calibrating the landing angle Θ_{LA} of the electron beam B may initially involve establishing a reference plane R which may be used to determine a tilt of the landing angle standard structure 10. In these embodiments, the reference plane R is defined as the wafer plane which is assumed absolutely horizontal. With the reference plane R established, the relative position of standard structure 10 to the reference plane can be determined, the method may further involve establishing a first target point 22 and a second target point 24, with the first target point 22 and the second target point 24 being located on a surface 12 of the landing angle standard structure 10. In these embodiments, the first target point 22 and the second target point 24 may be spaced apart from one another in at least one direction (e.g., in the x-direction or y-direction) by a target point distance T_{d}.

Referring still to FIG. 1, once the first target point 22 and the second target point 24 have been established on the surface 12 of the structure 10, a height of each of the first target point 22 and the second target point 24 may be determined relative the reference plane R. For example, as depicted in FIG. 1, the first target point 22 may be positioned a first target point height 22a from the reference plane R (e.g., in the vertical direction as depicted in FIG. 1), while the second target point 24 may be positioned a second target point height 24a from the reference plane R (e.g., in the vertical direction as depicted in FIG. 1).

In these embodiments, the surface 12 of the landing angle standard structure 10 may be flat (e.g., aligned with the reference plane R) when the first target point height 22a is equal to the second target point height 24a. However, in embodiments in which the first target point height 22a is different than the second target point height 24a, the landing angle standard structure 10 may be tilted relative the reference plane R. For example, as indicated in FIG. 1, the landing angle standard structure 10 may be tilted at a tilt angle Φ relative the reference plane R. In these embodiments, the tilt angle Φ may be determined utilizing the first target point height 22a, the second target point height 24a, and the target point distance T_{d}.

Calculation of the tilt angle Φ may initially involve determining a height difference between the first target point 22 and the second target point 24. In these embodiments, the height difference between the first target point 22 and the second target point 24 may be determined by subtracting the second target point height 24a from the first target point height 22a. Accordingly, in the embodiments described herein, the surface 12 of the landing angle standard structure 10 may be tilted upward (e.g., from second target point 24 to first target point 22) when the first target point height 22a is greater than the second target point height 24a, while the surface 12 of the landing angle standard structure 10 may be tilted downward (e.g., from the second target point 24 to the first target point 22).

Referring still to FIG. 1, once the height difference between the first target point 22 and the second target point 24 is determined, the tilt angle Φ may be calculated by determining the arctangent of the height difference divided by the target point distance Td. The equation for calculating the tilt angle Φ may be determined as follows:

$$Φ = {tan}^{- 1} ( ( first target point height - second target point height ) / {T}_{d} )$$

It should be further appreciated that, in the embodiments described herein, the landing angle standard structure 10 may be tilted in both in both X and Y in the reference XY plane direction. Accordingly, the tilt angle Φ may further include a tilt angle Φx and a tilt angle Φy. To determine the horizontal tilt angle Φx, the first target point 22 and the second target point 24 may be spaced apart from one another in a longitudinal direction (e.g., in the +/−x-direction as depicted in the coordinate axis of FIG. 1), as is illustrated in FIG. 1. Similarly, the same methodology described herein may be utilized to determine the tilt angle Φy by spacing the first target point 22 and the second target point 24 apart from one another in a lateral direction (e.g., in the +/−y-direction as depicted in the coordinate axis of FIG. 1). It should be understood that, in the embodiments described herein, the disclosed method of calibrating a landing angle of an electron beam may involve determining both tilt angle Φx and tilt angle Φy of the landing angle standard structure 10.

Referring now to FIGS. 2A-2C, once the tilt angle (e.g., the x- and y-tilt angle) of the landing angle standard structure 10 is determined, the method may further involve scanning the landing angle standard structure 10 with the electron beam B to capture SEM images of the structure of the landing angle standard structure 10. The various SEM images captured by the electron beam B may then be utilized to determine the beam tilt of the electron beam B in a particular direction (e.g., in the x-direction or the y-direction), as will be described in additional detail herein.

In these embodiments, the beam tilt of the electron beam B may be determined by analyzing the pair of sidewalls 20 of the landing angle standard structure 10. For example, in these embodiments, the landing angle standard structure 10 may include a first sidewall 26 and a second sidewall 28, with the first sidewall 26 and the second sidewall 28 each including a leading edge 26a, 28a and a trailing edge 26b, 28b. In these embodiments, the first sidewall 26 may further include a first sidewall width Wₛ₁ that may be defined as a distance between the leading edge 26a and the trailing edge 26b of the first sidewall 26. Similarly, the second sidewall 28 may further include a second sidewall width Wₛ₂ that may be defined as a distance between the leading edge 28a and the trailing edge 28b of the second sidewall 28.

As noted hereinabove, the pair of sidewalls 20 of the landing angle standard structure 10 may be fabricated such that the pair of sidewalls 20 are symmetrical. Accordingly, in the embodiments described herein, the first sidewall width Wₛ₁ may be equal to the second sidewall width Wₛ₂. However, when the electron beam B is tilted (e.g., has a beam tilt, as described herein), the SEM images of the landing angle standard structure 10 may depict the first sidewall width Wₛ₁ as being different from the second sidewall width Wₛ₂. Accordingly, the difference in width of the first sidewall width Wₛ₁ and the second sidewall width Wₛ₂ may be used to determine the beam tilt of the electron beam B in a particular direction (e.g., in the x-direction or the y-direction).

It should be appreciated that, in the embodiments described herein, the electron beam B may be tilted in multiple directions. That is, the electron beam B may have a beam tilt Θ_{BX} and/or a beam tilt Θ_{BY}. Accordingly, to determine the landing angle Θ_{LA} of the electron beam B, the beam tilt of the electron beam B in both the x-direction and the y-direction may be determined. In these embodiments, the x direction beam tilt Θ_{BX} may be determined by sweeping the electron beam B in a longitudinal direction (e.g., in the +/−x-direction as depicted in the coordinate axes of FIG. 2A-2C), while beam tilt θ_{BY} may be determined by sweeping the electron beam B in the lateral direction (e.g., in the +/−y-direction as depicted in the coordinate axes of FIGS. 2A-2C).

For example, FIGS. 2A-2C depict the electron beam B performing a sweep of the landing angle standard structure 10 in the longitudinal direction to determine the x-direction beam tilt Θ_{BX} of the electron beam B. In these embodiments, the sweep of the electron beam B is performed to obtain SEM images of the landing angle standard structure 10. These SEM images are then analyzed to determine the first sidewall width Wₛ₁ of the first sidewall 26 and the second sidewall width Wₛ₂ of the second sidewall 28.

As described herein, the first sidewall width Wₛ₁ is measured by determining the distance between the leading edge 26a and the trailing edge 28a of the first sidewall 26, while the second sidewall width Wₛ₂ is determined by measuring the distance between the leading edge 28a and the trailing edge 28b of the second sidewall 28. With the first sidewall width Wₛ₁ and the second sidewall width Wₛ₂ determined, a width difference W_{d} may be calculated by subtracting the second sidewall width Wₛ₂ from the first sidewall width Wₛ₁. In these embodiments, the width difference Wd may be used to determine the beam tilt (e.g., the x beam tilt Θ_{BX} as illustrated in FIGS. 2A-2C) using the following equation:

$${W}_{d} = 2 {Θ}_{B X \times } {H}_{s}$$

In these embodiments, Hₛ may be considered the height of each of the pair of sidewalls 20, which may be a predetermined value based on the fabrication process of the landing angle standard structure 10. Accordingly, having identified the width difference Wd and the height of the pair of sidewalls 20, it may be possible to determine the horizontal beam tilt Θ_{BX} of the electron beam B.

Referring again to FIGS. 2A-2C, electron beams B having various x beam tilt values Θ_{BX} are depicted. For example, as illustrated in FIG. 2A, the x-axis beam tilt Θ_{BX} of the electron beam may be less than zero (e.g., negative horizontal beam tilt Θ_{BX}) in embodiments in which the SEM images captured during the electron beam B scan depict the first sidewall width Wₛ₁ as being less than the second sidewall width Wₛ₂. In contrast, as illustrated in FIG. 2C, the x-axis beam tilt Θ_{BX} of the electron beam B may be greater than zero (e.g., positive beam tilt) in embodiments in which the SEM images captured during the electron beam B scan depict the first sidewall width Wₛ₁ as being greater than the second sidewall width Wₛ₂. Furthermore, as illustrated in FIG. 2B, embodiment in which the SEM images portray the first sidewall width Wₛ₁ as being equal to the second sidewall width Wₛ₂, the electron beam B may be aligned (e.g., having no beam tilt) in the direction in which electron beam B scan was performed (e.g., in the longitudinal direction as depicted in FIGS. 2A-2C).

Referring still to FIGS. 2A and 2C, and as described in detail herein, it should be further understood that the same methodology described herein may be utilized to determine a beam tilt θ_{BY} (e.g., in the +/−y-direction as depicted in the coordinate axes of FIGS. 2A-2C) of the electron beam B. For example, to determine the beam tilt θ_{BY} of the electron beam B, the beam scan performed to capture the SEM images of the landing angle standard structure 10 may be conducted in a lateral direction (e.g., in the +/−y-direction) as opposed to in the longitudinal direction depicted in FIGS. 2A-2C.

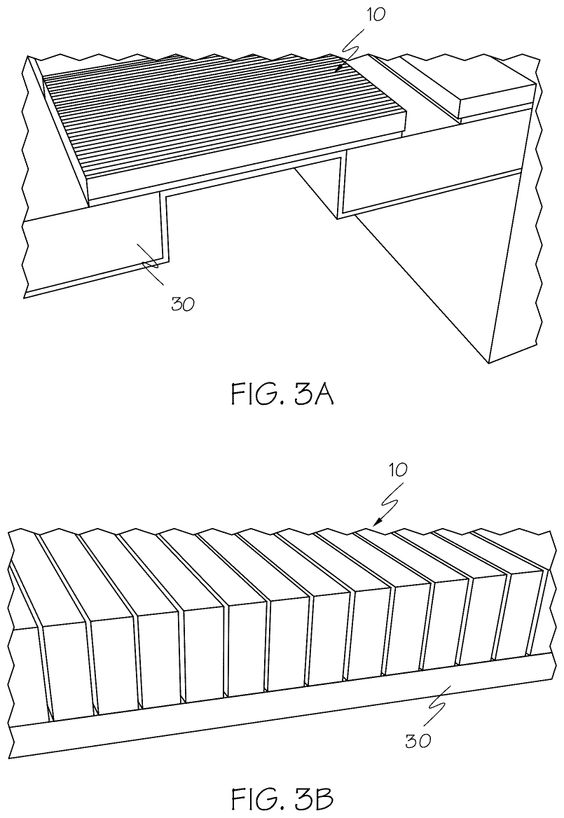

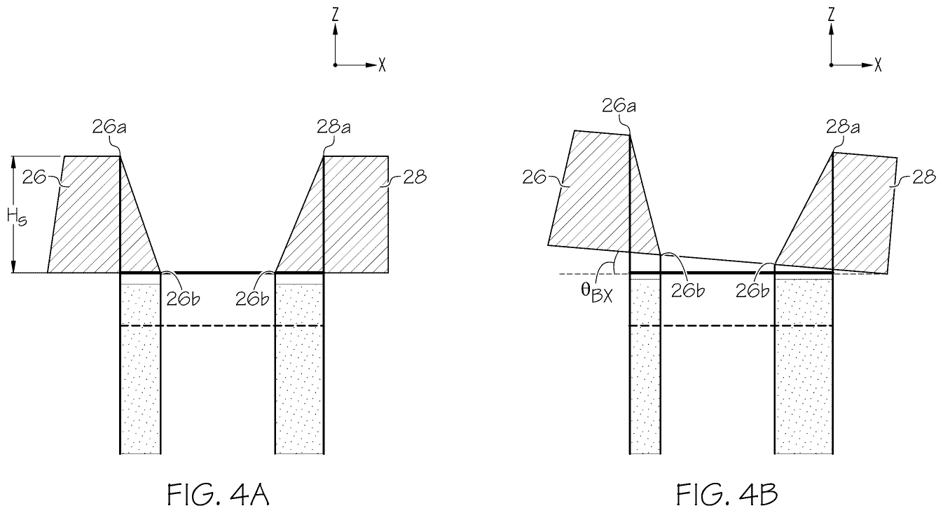

Turning now to FIGS. 3A and 3B, it should be further appreciated that, in order to effectively determine the beam tilt of the electron beam B, the leading edge 26a, 28a and the trailing edge 26b, 28b of each of the pair of sidewalls 20 may be distinguishable in the SEM images captured by the electron beam scan. In these embodiments, to aid in distinguishing the leading edge 26a, 28a and the trailing edge 26b, 28b of each of the pair of sidewalls 20, the landing angle standard structure 10 may be fabricated to include an imaging layer 30 deposited at the bottom layer of the structure 10, with the imaging layer 30 being configured to enhance the visibility of the leading edge 26a, 28a and the trailing edge 26b, 28b of each of the pair of sidewalls 20.

Turning now to FIGS. 3A and 3B, the relationship between the width difference W_{d} of the pair of sidewalls 20 and the beam tilt of the electron beam B is depicted in additional detail. For example, as depicted in FIG. 3A and described in detail herein, the first sidewall width Wₛ₁ and the second sidewall width Wₛ₂ may be equal when the electron beam B is normal to the surface 12 of the landing angle standard structure 10 (e.g., the electron beam B has no beam tilt). However, as depicted in FIG. 3B, beam tilt (e.g., either in x- or y-direction) may distort the measurements conducted by the electron beam B, such that the landing angle standard structure 10 appears tilted at an angle corresponding to the beam tilt of the electron beam B. For example, FIG. 3B depicts the landing angle standard structure as being tilted at an angle equivalent to the horizontal beam tilt Θ_{BX} depicted in FIG. 2A.

Referring now to FIGS. 1-3B collectively, once the tilt angle of the landing angle standard structure and the beam tilt of the electron beam B have been calculated, the method may advance to determining the landing angle Θ_{LA} of the electron beam. In these embodiments, the landing angle Θ_{LA} may include a x-direction landing angle Θ_{LAx} and a y-direction landing angle Θ_{LAy}, with each component of the landing angle Θ_{LA} being calculated as follows:

$${Θ}_{L A X} = {Φ}_{X} - {Θ}_{B X} \\ {Θ}_{L A Y} = {Φ}_{Y} - {Θ}_{B Y}$$

As depicted above, the landing angle Θ_{LA} may be determined by subtracting the beam tilt of the electron beam from the tilt angle (e.g., in x-direction and y-direction) of the landing angle standard structure. Accordingly, the method described herein may allow for a user calibrating the electron beam B to determine the landing angle Θ_{LA} at which the electron beam B is contacting the surface 12 of a structure in multiple planes (e.g., in the x-plane and y-plane). Using this information, the landing angle Θ_{LA} of the electron beam B may be minimized and/or eliminated, such that the electron beam B is calibrated and/or aligned as desired (e.g., the electron beam B is perpendicular to the reference plane R). In these embodiments, the landing angle Θ_{LA} may be accounted for by adjusting the electron beam B until the tilt angle of the landing angle standard structure 10 is equal to the beam tilt of the electron beam B (e.g., such that the beam tilt is normal to the reference plane R). However, in other embodiments, the electron beam B may be utilized to perform measurements without any adjustment, in which instances the landing angle Θ_{LA} of the electron beam B may be accounted for during analysis of the measurements acquired during operation of the electron beam B.

In view of the foregoing, it should be appreciated that the embodiments described herein are related to a method of calibrating a landing angle of an electron beam. As provided herein, the method may involve fabricating a landing angle standard structure, determining a tilt angle of the landing angle standard structure relative a reference plane, scanning the landing angle standard structure, to generate a plurality of images of the landing angle standard structure, determining a width difference between a first sidewall formed on the landing angle standard structure and a second sidewall formed on the landing structure, determining a beam tilt of the electron beam, determining the landing angle of the electron beam, and adjusting the electron beam, such that the landing angle of the electron beam is normal to a surface of the landing angle standard structure. In the embodiments described herein, it should be appreciated that, by determining and accounting for the landing angle of the electron beam, the method described herein may allow for more accurate measurements of structure while minimizing deviations between metrology tools.

The embodiments disclosed herein may be further described with reference to the following aspects:

According to one aspect of the disclosure, and potentially in combination with other disclosed aspects of the disclosure, a method of calibrating a landing angle of an electron beam includes fabricating a landing angle standard structure; determining a tilt angle of the landing angle standard structure relative a reference plane; scanning the landing angle standard structure, using the electron beam, to generate a plurality of images of the landing angle standard structure; determining, using the plurality of images of the landing angle standard structure, a width difference between a first sidewall formed on the landing angle standard structure and a second sidewall formed on the landing structure; determining, using the width difference between the first sidewall and the second sidewall, a beam tilt of the electron beam; determining, by comparing the beam tilt of the electron beam to the tilt angle of the landing angle standard structure, the landing angle of the electron beam; and adjusting the electron beam, such that the landing angle of the electron beam is normal to a surface of the landing angle standard structure.

According to one aspect of the disclosure, and potentially in combination with other disclosed aspects of the disclosure, fabricating the landing angle standard structure further involves fabricating the landing angle standard structure as a high aspect ratio structure.

According to one aspect of the disclosure, and potentially in combination with other disclosed aspects of the disclosure, the landing angle standard structure is fabricated such that the first sidewall is symmetrical to the second sidewall.

According to one aspect of the disclosure, and potentially in combination with other disclosed aspects of the disclosure, the landing angle standard structure is fabricated using at least one of reactive ion etching, deep reactive ion etching, cryogenic deep silicon etching, inductively coupled plasma etching, and wet etching.

According to one aspect of the disclosure, and potentially in combination with other disclosed aspects of the disclosure, determining the tilt angle of the landing angle standard structure relative the reference plane further involves identifying a first target point and a second target point positioned on the surface of the landing angle standard structure, with the first target point being spaced a target point distance from a second target point in at least one direction.

According to one aspect of the disclosure, and potentially in combination with other disclosed aspects of the disclosure, determining the tilt angle of the landing angle standard structure relative the reference point further includes measuring a first target point height between the first target point and the reference plane, and a second target point height between the second target point and the reference plane.

According to one aspect of the disclosure, and potentially in combination with other disclosed aspects of the disclosure, determining the tilt angle of the landing angle standard structure relative the reference point further includes determining an x-direction tilt angle of the landing angle standard structure relative the reference plane and a y-direction tilt angle of the landing angle relative the reference plane.

According to one aspect of the disclosure, and potentially in combination with other disclosed aspects of the disclosure, determining the width difference between the first sidewall and the second sidewall further includes determining a first sidewall width and a second sidewall width.

According to one aspect of the disclosure, and potentially in combination with other disclosed aspects of the disclosure, the first sidewall includes a first sidewall leading edge and a first sidewall trailing edge, and the first sidewall width is determined by calculating a distance between the first sidewall leading edge and the first sidewall trailing edge.

According to one aspect of the disclosure, and potentially in combination with other disclosed aspects of the disclosure, the second sidewall includes a second sidewall leading edge and a second sidewall trailing edge, and the second sidewall width is determined by calculating the distance between the second sidewall leading edge and the second sidewall trailing edge.

According to one aspect of the disclosure, and potentially in combination with other disclosed aspects of the disclosure, determining the beam tilt of the electron beam further involves comparing the width difference to a height of the first sidewall and the second sidewall.

According to one aspect of the disclosure, and potentially in combination with other disclosed aspects of the disclosure, determining the beam tilt of the electron beam further includes determining an x-direction beam tilt and a y-direction beam tilt of the electron beam.

According to one aspect of the disclosure, and potentially in combination with other disclosed aspects of the disclosure, fabricating the landing angle standard structure further involves disposing an imaging layer at the bottom of the structure.

According to one aspect of the disclosure, and potentially in combination with other disclosed aspects of the disclosure, the reference plane is a horizontal plane.

According to one aspect of the disclosure, and potentially in combination with other disclosed aspects of the disclosure, a method of calibrating a landing angle of an electron beam includes fabricating, using an etching process, a landing angle standard structure having a pair of sidewalls, each of the pair of sidewalls being symmetrical; determining a tilt angle of the landing angle standard structure relative a reference plane, scanning the landing angle standard structure, using the electron beam, to generate a plurality of images of the landing angle standard structure; determining, using the plurality of images of the landing angle standard structure, a width difference between the pair of sidewalls of the landing angle standard structure; determining, by comparing the width difference between the pair of sidewalls and a height of the pair of sidewalls, a beam tilt of the electron beam; determining, by comparing the beam tilt of the electron beam to the tilt angle of the landing angle standard structure, the landing angle of the electron beam; and adjusting the electron beam, such that the landing angle of the electron beam is normal to a surface of the landing angle standard structure; wherein fabricating the landing angle standard structure further includes fabricating the landing angle standard structure as a high aspect ratio structure.

According to one aspect of the disclosure, and potentially in combination with other disclosed aspects of the disclosure, determining the tilt angle of the landing angle standard structure relative the reference point further includes determining an x-direction tilt angle of the landing angle standard structure relative the reference plane and a y-direction tilt angle of the landing angle relative the reference plane.

According to one aspect of the disclosure, and potentially in combination with other disclosed aspects of the disclosure, determining the beam tilt of the electron beam further includes determining an x-direction beam tilt and a y-direction beam tilt of the electron beam.

According to one aspect of the disclosure, and potentially in combination with other disclosed aspects of the disclosure, determining the landing angle of the electron beam further includes determining an x-direction landing angle and a y-direction landing angle of the electron beam.

According to one aspect of the disclosure, and potentially in combination with other disclosed aspects of the disclosure, fabricating the landing angle standard structure further includes disposing a layer at the bottom of the structure.

According to one aspect of the disclosure, and potentially in combination with other disclosed aspects of the disclosure, a method of fabricating a landing angle standard structure for calibrating a landing angle of an electron beam includes forming, using an etching process, the landing angle standard structure, such that the landing angle standard structure includes a pair of symmetrical sidewalls and a high aspect ratio, disposing an imaging layer at the bottom of the landing angle standard structure, the imaging layer being formed of a first material that is different than a second material used to form the landing angle standard structure; and disposing the landing angle standard structure within an environment of the electron beam, such that the surface of the landing angle standard structure has a tilt angle relative the electron beam.

The terminology used herein is for the purpose of describing particular aspects only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. The term “or a combination thereof” means a combination including at least one of the foregoing elements.

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A method of calibrating a landing angle of an electron beam, the method comprising:
fabricating a landing angle standard structure;
determining a tilt angle of the landing angle standard structure relative a reference plane;
scanning the landing angle standard structure, using the electron beam, to generate a plurality of images of the landing angle standard structure;
determining, using the plurality of images of the landing angle standard structure, a width difference between a first sidewall formed on the landing angle standard structure and a second sidewall formed on the landing structure;
determining, using the width difference between the first sidewall and the second sidewall, a beam tilt of the electron beam;
determining, by comparing the beam tilt of the electron beam to the tilt angle of the landing angle standard structure, the landing angle of the electron beam; and
adjusting the electron beam, such that the landing angle of the electron beam is normal to a surface of the landing angle standard structure.

2. The method of claim 1, wherein fabricating the landing angle standard structure further involves fabricating the landing angle standard structure as a high aspect ratio structure.

3. The method of claim 1, wherein the landing angle standard structure is fabricated such that the first sidewall is symmetrical to the second sidewall.

4. The method of claim 1, wherein the landing angle standard structure is fabricated using at least one of reactive ion etching, deep reactive ion etching, cryogenic deep silicon etching, inductively coupled plasma etching, and wet etching.

5. The method of claim 1, wherein determining the tilt angle of the landing angle standard structure relative the reference plane further involves identifying a first target point and a second target point positioned on the surface of the landing angle standard structure, with the first target point being spaced a target point distance from a second target point in at least one direction.

6. The method of claim 5, wherein determining the tilt angle of the landing angle standard structure relative the reference point further includes measuring a first target point height between the first target point and the reference plane, and a second target point height between the second target point and the reference plane.

7. The method of claim 1, wherein determining the tilt angle of the landing angle standard structure relative the reference point further includes determining an x-direction tilt angle of the landing angle standard structure relative the reference plane and a y-direction tilt angle of the landing angle relative the reference plane.

8. The method of claim 1, wherein determining the width difference between the first sidewall and the second sidewall further includes determining a first sidewall width and a second sidewall width.

9. The method of claim 8, wherein the first sidewall includes a first sidewall leading edge and a first sidewall trailing edge, and the first sidewall width is determined by calculating a distance between the first sidewall leading edge and the first sidewall trailing edge.

10. The method of claim 9, wherein the second sidewall includes a second sidewall leading edge and a second sidewall trailing edge, and the second sidewall width is determined by calculating the distance between the second sidewall leading edge and the second sidewall trailing edge.

11. The method of claim 1, wherein determining the beam tilt of the electron beam further involves comparing the width difference to a height of the first sidewall and the second sidewall.

12. The method of claim 1, wherein determining the beam tilt of the electron beam further includes determining an x-direction beam tilt and a y-direction beam tilt of the electron beam.

13. The method of claim 1, wherein fabricating the landing angle standard structure further involves disposing an imaging layer at the bottom of the structure.

14. The method of claim 1, wherein the reference plane is a horizontal plane

15. A method of calibrating a landing angle of an electron beam, the method comprising:
fabricating, using an etching process, a landing angle standard structure having a pair of sidewalls, each of the pair of sidewalls being symmetrical;
determining a tilt angle of the landing angle standard structure relative a reference plane,
scanning the landing angle standard structure, using the electron beam, to generate a plurality of images of the landing angle standard structure;
determining, using the plurality of images of the landing angle standard structure, a width difference between the pair of sidewalls of the landing angle standard structure;
determining, by comparing the width difference between the pair of sidewalls and a height of the pair of sidewalls, a beam tilt of the electron beam;
determining, by comparing the beam tilt of the electron beam to the tilt angle of the landing angle standard structure, the landing angle of the electron beam; and
adjusting the electron beam, such that the landing angle of the electron beam is normal to a surface of the landing angle standard structure;
wherein fabricating the landing angle standard structure further includes fabricating the landing angle standard structure as a high aspect ratio structure.

16. The method of claim 15, wherein determining the tilt angle of the landing angle standard structure relative the reference point further includes determining an x-direction tilt angle of the landing angle standard structure relative the reference plane and a y-direction tilt angle of the landing angle relative the reference plane.

17. The method of claim 15, wherein determining the beam tilt of the electron beam further includes determining an x-direction beam tilt and a y-direction beam tilt of the electron beam.

18. The method of claim 15, wherein determining the landing angle of the electron beam further includes determining an x-direction landing angle and a y-direction landing angle of the electron beam.

19. The method of claim 15, wherein fabricating the landing angle standard structure further includes disposing an layer at the bottom of the structure.

20. A method of fabricating a landing angle standard structure for calibrating a landing angle of an electron beam, the method comprising:
forming, using an etching process, the landing angle standard structure, such that the landing angle standard structure includes a pair of symmetrical sidewalls and a high aspect ratio,
disposing an imaging layer at the bottom of the landing angle standard structure, the imaging layer being formed of is different than the material used for landing angle standard structure.
disposing the landing angle standard structure within an environment of the electron beam, such that the surface of the landing angle standard structure has a tilt angle relative the electron beam.
